(19) United States
(12) Patent Application Publication
(10) Pub. No.: US 2024/0240937 A1
(43) Pub. Date: Jul. 18, 2024

(54) Depth Measurement Device, Depth Measurement System, and Depth Index Calculation Method

(71) Applicant: Hitachi High-Tech Corporation, Minato-ku, Tokyo (JP)

(72) Inventors: Aoi YAMAUCHI, Tokyo (JP); Ayumi DOI, Tokyo (JP); Makoto SUZUKI, Tokyo (JP); Shuuichirou TAKAHASHI, Tokyo (JP); Masaki SUGIE, Tokyo (JP)

(21) Appl. No.: 18/559,162

(22) PCT Filed: May 28, 2021
(86) PCT No.: PCT/JP2021/020550

§ 371 Date: Nov. 6, 2023

(51) Int. Cl. G01B 15/00

(52) U.S. Cl. CPC G01B 15/00

(57) ABSTRACT

Provided is a depth measurement system comprising a plurality of depth measurement devices which each calculate a depth index value indicating the relative depth of a pattern on a sample, wherein: the plurality of depth measurement devices are classified into one reference device 1001 and an other correction target device 1002; the depth measurement devices each execute a depth measurement recipe for measuring the depth of a predetermined pattern in a measurement subject so as to calculate the depth index value of the predetermined pattern on the basis of a measurement value extracted from an obtained electronic image; and the correction target device stores a correction coefficient associated with the depth measurement recipe and outputs the depth index value of the predetermined pattern which has been corrected using a mathematical model to which the correction coefficient is applied.

### TECHNICAL FIELD

The present invention relates to a depth measurement device, a depth measurement system, and a depth index calculation method for measuring a depth of a pattern, particularly, a depth of a depression such as a hole or a trench.

### BACKGROUND ART

In recent years, demands for measuring three-dimensional shapes have increased due to complication and three-dimensionality of semiconductors, and thus schemes of measuring three-dimensional shapes with critical dimension-scanning electron microscope (SEM) have been proposed. PTL 1 discloses a scheme of finding linearity between a depth of a trench or a hole and (trench width/luminance of trench bottom)^{N} in a trench structure or (area of a hole/luminance of hole bottom)^{N} in a hole structure and measuring a depth of a depression such as the trench or the hole from a line width or an area of a pattern and a luminance value (signal amount) of an inner side (bottom) of the pattern.

### CITATION LIST

### Patent Literature

PTL 1: WO2020/095346A

### SUMMARY OF INVENTION

### Technical Problem

In PTL 1, an index value proportional to a depth (hereinafter referred to as a depth index value) is calculated from the line width or the area of the pattern and the luminance value of the bottom of the pattern, and an absolute value of a pattern depth is calculated using a database that stores a relationship between pattern depths measured in advance and depth index values. However, when this method is used to manage a semiconductor device manufacturing process, the line width or the area of the pattern for calculating the depth index value is measured by a plurality of depth measurement devices disposed in a production line. However, since there is a device difference between depth measurement devices due to various factors, the device difference between devices arises in the depth index value calculated from the measured values. The present disclosure relates to correction of the device difference in the depth index value arising between depth measurement devices.

### Solution to Problem

A depth measurement system according to an aspect of the present disclosure is a depth measurement system including a plurality of depth measurement devices, each of the plurality of depth measurement devices calculating a depth index value indicating a relative depth of a pattern on a sample.

Each of the depth measurement devices includes an electron optical system that irradiates the sample with an electron beam, a detection system that detects an emission electron emitted from the sample irradiated with the electron beam, and a computer that controls the electron optical system and the detection system by executing a depth measurement recipe that is an operation program measuring a depth of a predetermined pattern in a measurement target and calculates the depth index value of the predetermined pattern based on a measured value extracted from an electron image formed from an output from the detection system.

The plurality of depth measurement devices are classified into one reference device and the other correction target devices.

The computer of the correction target device stores a correction coefficient associated with the depth measurement recipe and outputs the depth index value of the predetermined pattern corrected using a mathematical model to which the correction coefficient is applied.

### Advantageous Effects of Invention

It is possible to reduce a device difference arising due to a magnification error, a gain difference of the detection system, or the like between the reference device and the correction target device. Other problems and new features will be apparent from description and appended drawings of the present specification.

### BRIEF DESCRIPTION OF DRAWINGS

FIG. 1 is a schematic view illustrating a depth measurement device.

FIG. 2A is a diagram illustrating an example of a depth measurement system.

FIG. 2B is a diagram illustrating a device difference correction flow of a depth index value.

FIG. 3 is a diagram illustrating a correction coefficient calculation flow (Correction Method 1) of the depth index value.

FIG. 4A is a diagram illustrating an example of a correction coefficient management screen.

FIG. 4B is a diagram illustrating an example of a correction coefficient edit screen.

FIG. 5 is a diagram illustrating a correction coefficient calculation flow (Correction Method 2) of the depth index value.

FIG. 6A is a diagram illustrating a calculation example of a dimension value and a luminance value from an SEM image.

FIG. 6B is a diagram illustrating the calculation example of the dimension value and the luminance value from the SEM image.

FIG. 7A is a diagram illustrating the calculation example of the dimension value and the luminance value from the SEM image.

FIG. 7B is a diagram illustrating the calculation example of the dimension value and the luminance value from the SEM image.

FIG. 8 is a diagram illustrating a correction coefficient calculation flow (Correction Method 3) of the depth index value.

FIG. 9A is a diagram illustrating an example of the correction coefficient management screen.

FIG. 9B is a diagram illustrating an example of the correction coefficient edit screen.

FIG. 10 is a diagram illustrating an example of the depth measurement system.

FIG. 11 is a diagram illustrating a calculation and operation flow of a correction coefficient in the depth measurement system.

FIG. 12A is a diagram illustrating an example of a selection screen.

FIG. 12B is a diagram illustrating an example of a calculation result display screen.

### DESCRIPTION OF EMBODIMENTS

Hereinafter, an embodiment will be described with reference to the appended drawings. In the appended drawings, the same functional elements are displayed with the same or corresponding numbers in some cases. The appended drawings illustrate embodiments and implementation examples conforming to principles of the present disclosure. These drawings are illustrated to understand the present disclosure and are not used to interpret the present disclosure to a limited extent. The description of the present specification is typically exemplary and does not limit the claims or applied examples of the present disclosure in a sense.

The embodiment will be described in sufficient details to be carried out by those skilled in the art. However, other implementation forms are also possible, and it is necessary to understand that configurations and structures can be modified or replaced with various elements without departing from the scope or technical spirit of the present disclosure. Accordingly, the following technology is not to be construed to be limited.

In description of the following embodiment, examples in which the present disclosure is applied to a scanning electron microscope (SEM) using an electron beam as a depth measurement device or a depth measurement system will be described. However, the embodiments are not to be construed to be limited. The present disclosure can be applied to a device or a system using another microscope such as a transmission electron microscope (TEM), a projection electron microscope, or a surface irradiation electron microscope instead of the scanning electron microscope. The present disclosure can be applied to a device, a system, or a general observation system in which the above-described electron microscope is configured using a plurality of electron beams (multi-beams).

In functions, operations, processes, and flows of embodiments to be described below, a flow of each element or each step will be described using a “computer,” a “whole control unit”, or a “management computer” as a subject (operation entity). However, the “depth measurement device” or the “depth measurement system” may serve as a subject (operation subject) in description, or “various programs” executed by the computer may serve as a subject (operation entity) in description. Some or all of programs may be implemented by dedicated hardware or may be modularized. Various programs may be installed in a computer system by a program distribution server or a storage medium.

With complication and miniaturization of semiconductor devices, etching is an important process that has an influence on performance of devices. A depth measurement device according to the present example calculates a depth index value indicating a relative depth of a pattern based on a dimension value of a two-dimensional pattern and a luminance value inside a pattern obtained using the scanning electron microscope.

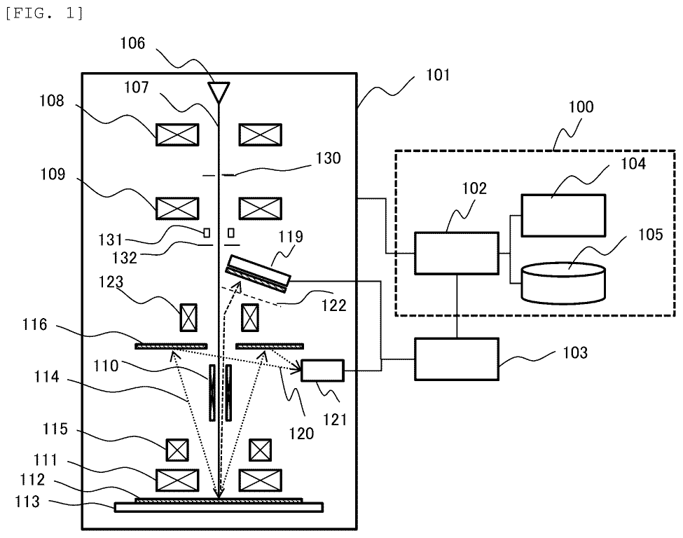

FIG. 1 is a schematic view illustrating the depth measurement device measuring a dimension of the depth of the pattern. The depth measurement device includes an imaging unit 101, a whole control unit 102, a signal processing unit 103, an input/output unit 104, and a storage unit 105.

The imaging unit 101 includes an electron gun 106, a focusing lens 108 that focuses an electron beam 107 emitted from the electron gun 106, and a focusing lens 109 that further focuses the electron beam 107 passing through the focusing lens 108. The imaging unit 101 further includes a deflector 110 that deflects the electron beam 107 and an objective lens 111 that controls a height of the focusing of the electron beam 107. A shutter 130 that partially limits the passing of the electron beam 107, a blanking deflector 131 that limits arrival of the electron beam at a sample 112 by deflecting the electron beam 107 out of an optic axis, and a blanking electrode 132 that receives the electron beam 107 deflected by the blanking deflector 131 are provided.

The sample 112 placed on a stage 113 is irradiated with the electron beam 107 passing through optical elements (the optical elements are generally called an electron optical system) related to irradiation or scanning with the electron beam. An emission electron 114 such as a secondary electron (SE) or a backscattered electron (BSE) emitted from the sample irradiated with the electron beam 107 is guided in a predetermined direction by a deflector 115 for deflecting emission electrons (first secondary electron aligner). The deflector 115 is a so-called wien filter and selectively deflects the emission electron 114 in a predetermined direction without deflecting the electron beam 107.

The emission electron 114 passing through a detection diaphragm 116 provided for angle discrimination of the emission electron 114 is guided to a detector 119 disposed out of an axis by a deflector 123 (second secondary electron aligner). A detector 121 that detects a secondary electron (cubic electron 120) generated due to collision of the emission electron 114 with the detection diaphragm 116 is also provided. An energy filter 122 is provided immediately before the detector 119, and by discriminating energy, it is possible to selectively detect the secondary electron that is emitted vertically upward from the bottom of a semiconductor pattern formed on the sample 112 and has a passing trajectory near the optic axis. The optical elements related to detection of the emission electron 114, as described above, are generally called a detection system.

The signal processing unit 103 generates an SEM image based on an output from the detection system. The signal processing unit 103 generates image data by storing a detection signal in a frame memory or the like in synchronization with scanning of a scanning deflector (not illustrated). When storing the detection signal in the frame memory, a signal profile (one-dimensional information) and the SEM image (two-dimensional information) are generated by storing the detection signal in a position corresponding to a scanning position of the frame memory.

The electron optical system and the detection system of the foregoing imaging unit 101 are controlled by the whole control unit 102. The whole control unit 102, the input/output unit 104, and the storage unit 105 are implemented as a computer 100. The whole control unit 102 receives a user's instruction from the input/output unit 104, reads a program and data stored in the storage unit 105, and executes a process. The program stored in the storage unit 105 is executed to execute a control process of acquiring an SEM image of a sample by the imaging unit 101, a calculation process of calculating the depth index value, and the like.

A method of measuring a depth in the depth measurement device illustrated in FIG. 1 will be described. The depth measurement device in FIG. 1 captures a SEM image of a pattern having a depression. A pattern dimension value or a pattern area of the depression and a luminance value inside the pattern are measured from the captured SEM image to calculate the depth index value. The depth index value is expressed as (Formula 1). N is any positive number and an appropriate value is set in accordance with a shape of the pattern or a material of the sample.

$$Depth index value = {( pattern dimension value or pattern area / pattern luminance value )}^{N} \qquad ( Formula 1 )$$

In the calculation of the depth index value, whether to use the pattern dimension value or the pattern area depends on a shape of a two-dimensional pattern of the depression. When the two-dimensional shape of the depression is an open pattern, the pattern dimension value is used. For example, a pattern dimension value of a trench width can be used for a trench pattern. Conversely, when the two-dimensional pattern shape of the depression is a closed pattern, the pattern area is used. For example, the pattern area is used for a hole pattern or a pattern with a planar shape such as an ellipse, a square, or a rectangle.

### Example 1

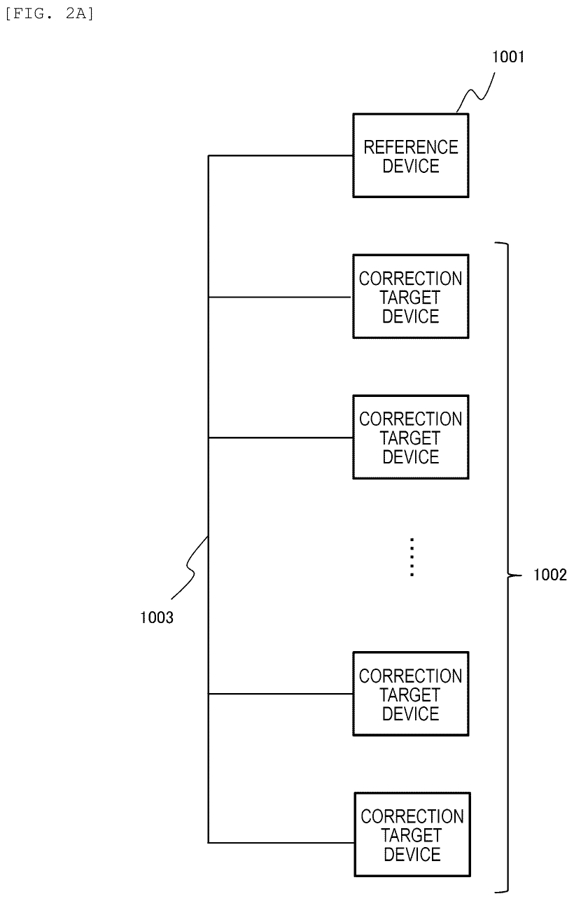

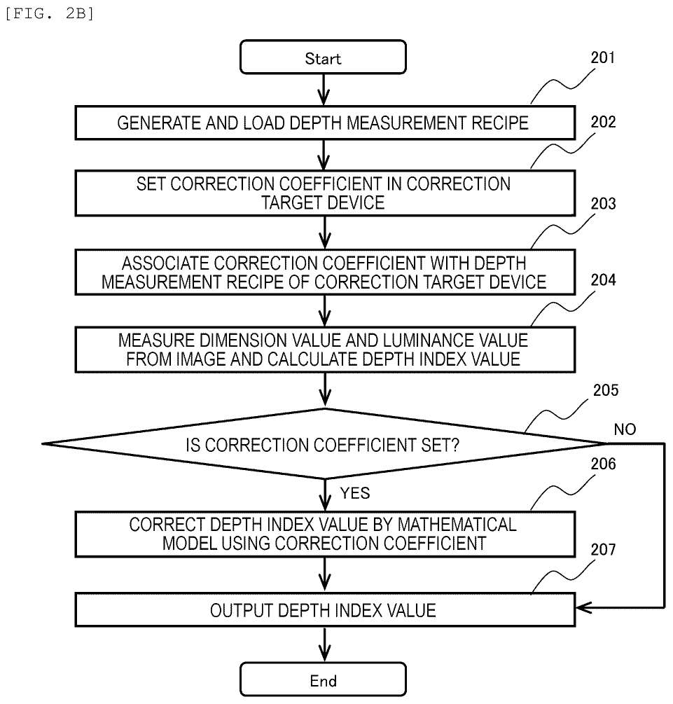

A plurality of depth measurement devices illustrated in FIG. 1 are used. In the depth measurement system in which each depth measurement device calculates a depth index value, a procedure of correcting a device difference between the depth measurement devices is illustrated in a flowchart of FIG. 2B. A case in which a measurement target is a produced wafer and a depth of a predetermined pattern formed on the produced wafer is measured by the plurality of depth measurement devices disposed in a wafer production line will be assumed.

As illustrated in FIG. 2A, to reduce the device difference from depth index values calculated by the plurality of depth measurement devices, one of the plurality of depth measurement devices is set as a reference device 1001 to perform correction for adjusting measured values of the other devices (referred to as correction target devices 1002) to a measured value of the reference device. Any one of the plurality of depth measurement devices is selected as the reference device 1001. Both the reference device 1001 and the correction target devices 1002 have the device configuration illustrated in FIG. 1. The whole control unit 102 (computer 100) of each device is preferably connected to each other via a network 1003. Hereinafter, the flowchart of FIG. 2B will be described.

In any one device (which may be the reference device or the correction target device) among the plurality of depth measurement devices, necessary information such as a layout of a wafer to be measured, coordinates of a measurement pattern, and a measurement condition is input from the input/output unit 104, and a measurement recipe (operation program) for depth measurement is generated and stored in the storage unit 105. The generated measurement recipe is loaded in the other depth measurement devices and is stored (step 201).

Subsequently, in each of the correction target devices 1002, a device difference correction coefficient of the depth index value is input from the input/output unit 104 and is stored in the storage unit 105 (step 202). Details of a method of determining the device difference correction coefficient will be described below. It is necessary to calculate and set the correction coefficient in advance for each measurement sample, each depth measurement condition, or each correction target device.

Subsequently, in each of the correction target devices 1002, the measurement recipe is associated so that the set device difference correction coefficient is applied to a depth measurement result (step 203).

Each depth measurement device executes the depth measurement recipe, measures a dimension value and a luminance value from a captured image, and calculates the depth index value (step 204). The depth index value is expressed as (Formula 1) and a value of an appropriate N in the depth measurement recipe is set. At this time, when the correction coefficient of the depth index value is applied to the measurement recipe (Yes in step 205), the depth measurement device corrects the depth index value using a mathematical model for correcting the depth index value to which the correction coefficient is applied (step 206). A measurement result after correction is output to the input/output unit 104 and is stored in the storage unit 105 (step 207). Conversely, when the correction coefficient is not set (No in step 205), the measurement result is output to the input/output unit 104 and stored in the storage unit 105 without correcting the measurement result (step 207). The case where the correction coefficient is not set includes a case where the depth measurement device is the reference device, and a case where the depth measurement device is the correction target device, but the device difference is small enough to be regarded as 0 and the correction coefficient is not set.

By correcting the depth index value of the correction target device 1002 using the mathematical model in this way, it is possible to reduce a device difference arising due to a magnification device difference or a gain difference of the detection system, or another factor between the reference device 1001 and the correction target device 1002. Hereinafter, serval examples of a method of correcting the depth index value will be described.

### (Correction Method 1 for Depth Index Value)

Correction Method 1 is a method of correcting the depth index value through linear correction using a linear formula as the mathematical model for correcting the depth index value. When I_{c} is a depth index value after correction, Iₒ is a depth index value calculated by the correction target device 1002 in accordance with (Formula 1) in step 204, and A and B are the correction coefficients set in step 202, the depth index value is corrected by a linear correction formula shown in (Formula 2).

$${I}_{c} = A \cdot {I}_{o} + B \qquad ( Formul a 2 )$$

A procedure of calculating the correction coefficients A and B when the device difference correction is executed in accordance with Correction Method 1 is illustrated in a flowchart of FIG. 3.

Since the correction coefficients A and B are obtained by executing fitting by the linear formula shown in (Formula 2), it is necessary to execute depth measurement at a plurality of measurement points on the measurement target wafer. Therefore, in any one device (which may be the reference device or the correction target device) among the plurality of depth measurement devices, necessary information such as a layout of a wafer to be measured, coordinates of a measurement pattern, and a measurement condition is input from the input/output unit 104, and a depth measurement recipe (operation program) for correction coefficient calculation is generated and stored in the storage unit 105. The generated measurement recipe is loaded in the other depth measurement devices and is stored (step 301). The measurement recipe is a measurement recipe in which only measurement points are different from those of the measurement recipe generated in step 201 of FIG. 2B.

The reference device 1001 executes the depth measurement recipe for correction coefficient calculation, measures the pattern dimension value and the pattern luminance value, and calculates the depth index value by (Formula 1) from these values (step 302). Similarly, the correction target device 1002 executes the depth measurement recipe for correction coefficient calculation on the same sample (measurement target), measures the pattern dimension value and the pattern luminance value, and calculates the depth index value by (Formula 1) from these values (step 303).

On the assumption that y is a depth index value at each measurement point by the reference device 1001 and x is a depth index value at each measurement point by the correction target device, fitting is executed by a linear formula (y=Ax+B) and the correction coefficients A and B are calculated (step 304). The calculated correction coefficients A and B are registered in the storage unit 105 of the correction target device 1002 (step 305). It is checked whether the correction coefficients are registered in all the correction target devices 1002. When there is a correction target device in which the correction coefficient is not registered, steps 303 to 305 are executed on that correction target device.

Magnitude of the device difference differs depending on the measurement condition in the depth measurement or the measurement target sample. Accordingly, as a principle, it is necessary to determine the correction coefficient for each depth measurement recipe (see step 201). On the other hand, when there is a depth measurement recipe (for example, a measurement recipe in which only measurement points are different) of which measurement conditions related to the device difference and the measurement target are the same as those of the depth measurement recipe, and when the correction coefficient is already calculated, there is no problem in using the correction coefficient calculated in the known depth measurement recipe as it is. In this case, calculation of the correction coefficient for a new depth measurement recipe can be omitted. The measurement conditions related to the device difference are an optical condition, an imaging magnification, the number of pixels, a scanning method, and the like.

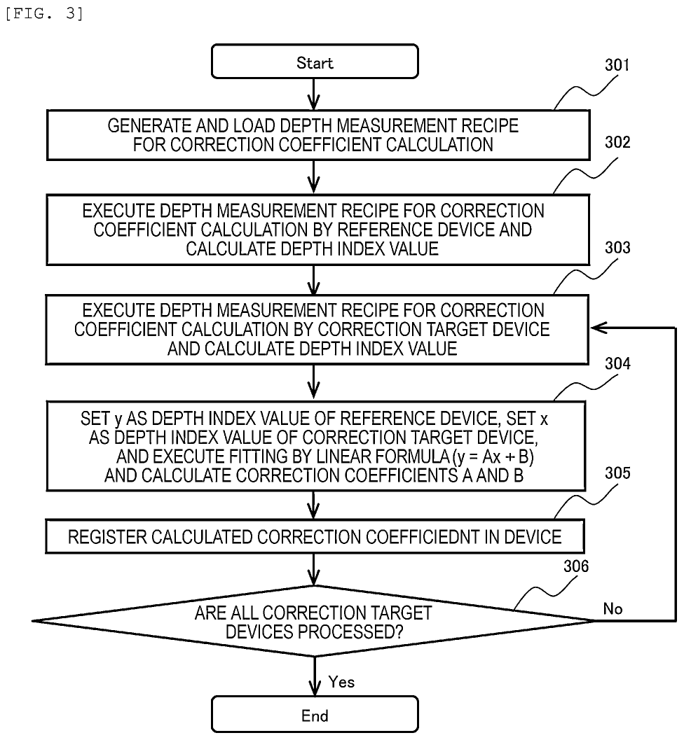

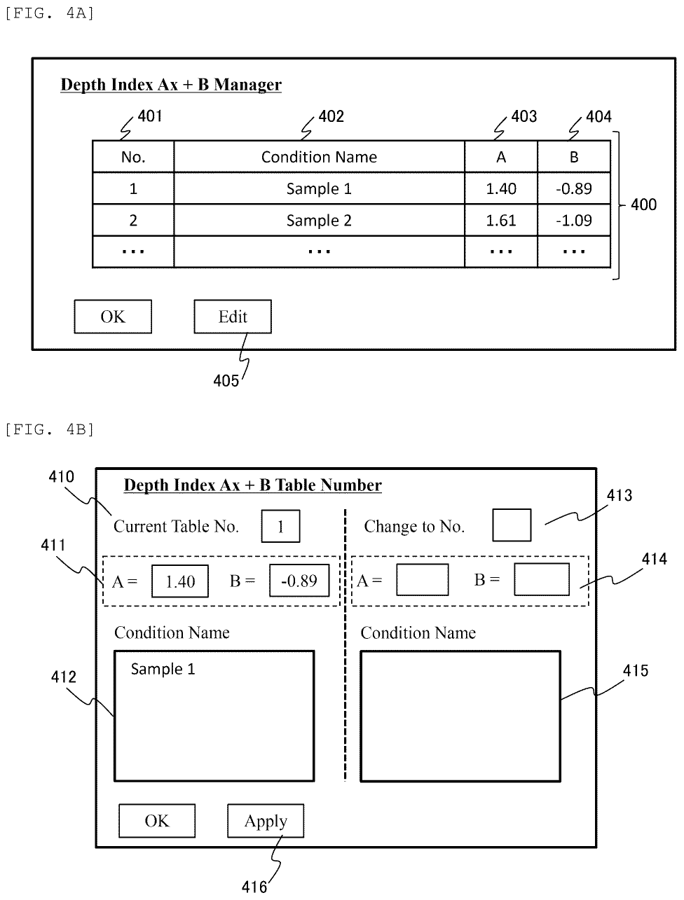

FIGS. 4A and 4B illustrate GUI screens for registering the correction coefficients A and B in the correction target device 1002 in step 305.

FIG. 4A illustrates a correction coefficient management screen. In a correction coefficient management table 400, the correction coefficients A and B registered in the correction target device 1002 can be checked collectively. The correction coefficient is managed with a management number 401, and a condition name 402 and correction coefficient values (A and B) 403 and 404 are registered for each management number. In the condition name 402, a measurement condition related to the above-described device difference and the measurement target are registered. The user can determine whether to calculate the correction coefficients and whether to apply the registered correction coefficients by checking the condition name 402.

The correction coefficient management table 400 can be edited from an edit button 405. A new record can be added, or the management number 401 can be selected to edit the condition name 402 and the correction coefficient values 403 and 404. FIG. 4B illustrates a correction coefficient edit screen. When a management number is selected and the edit button 405 is pressed, the management number of the currently selected correction coefficients is shown in a management number display field 410 on the edit screen, the correction coefficients registered with the management number are shown in a correction coefficient display field 411, and the condition name is shown in a condition name display field 412. A management number with which a correction coefficient is newly stored is input to a management number input field 413, the correction coefficients obtained in the flowchart of FIG. 3 are input to a correction coefficient value input field 414, and a condition name to be registered is input to a condition name input field 415. Thereafter, when an application button 416 is pressed, the correction coefficient management table 400 is updated.

### (Correction Method 2 for Depth Index Value)

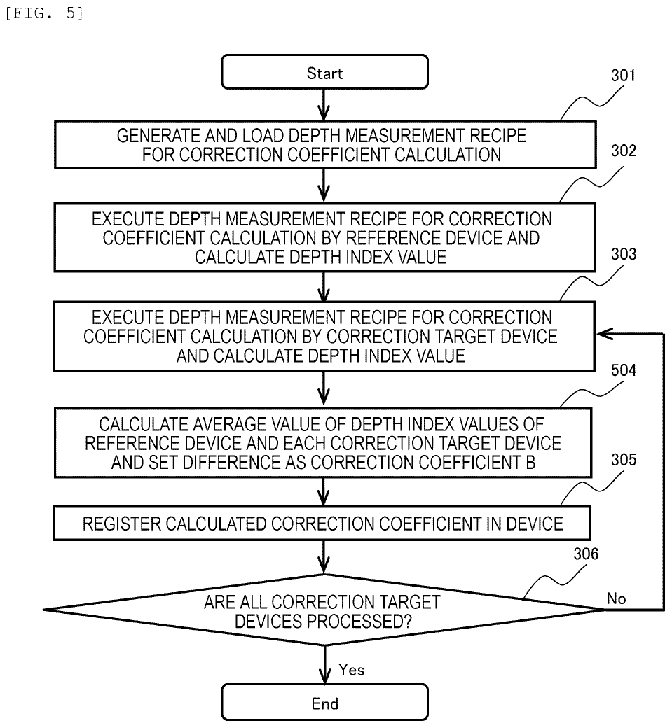

A method of correcting the depth index value is not limited to the above-described method. Correction Method 2 is a method of fixing the correction coefficient A to 1 and setting only the correction coefficient B in the mathematical model (Formula 2) of Correction Method 1. A procedure of calculating the correction coefficient B is illustrated in the flowchart of FIG. 5. Since steps 301 to 303, 305, and 306 are the same as those of the flowchart of FIG. 3, repeated description thereof will be omitted. In Correction Method 2, a difference between average values of the depth index values calculated by the reference device and the correction target devices is obtained and this difference is set as the correction coefficient B (step 504).

GUI screens for registering and managing the correction coefficients are similar to the screens illustrated in FIGS. 4A and 4B and are screens on which the correction coefficient A is fixed to 1 or the correction coefficient A is not displayed.

In the case of Correction Method 2, it is not necessary to execute the fitting by the linear formula. By calculating an offset amount from the average value of the depth index values calculated by each device, the correction coefficients can be calculated. Therefore, the correction coefficient values can be obtained more simply than in Correction Method 1.

### (Correction Method 3 for Depth Index Value)

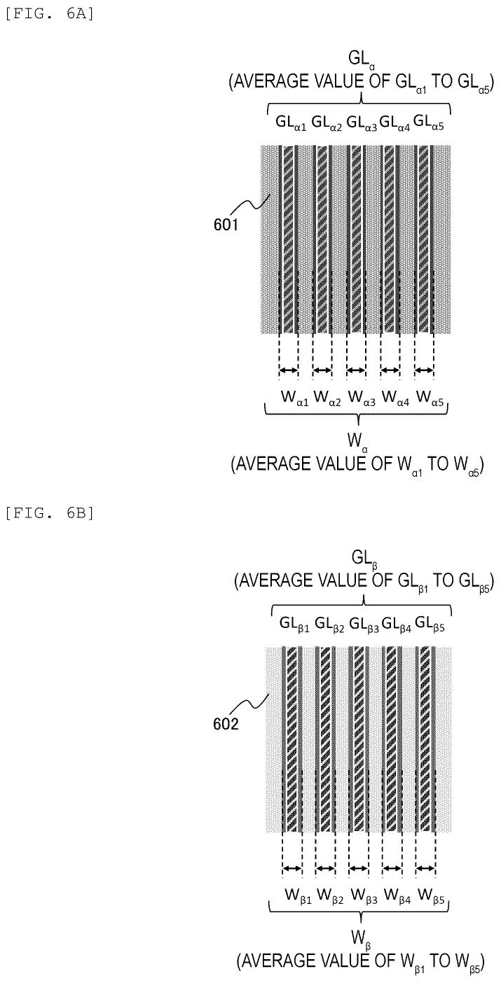

In Correction Method 3, the depth index values are corrected nonlinearly by correcting the pattern dimension value or the pattern area and the luminance value by each appropriate mathematical model and calculating the depth index values from the values after correction. FIGS. 6A and 6B illustrate examples in which a trench width and a luminance value are calculated from SEM images of the same trench pattern imaged by depth inspection devices α and β. In the trench patterns in SEM images 601 and 602, brightness or a trench width differs due to a magnification device difference of each device, a device difference of the detection system, or the like. W_{α} is a trench width obtained from the SEM image 601 captured by the device α (serving as the reference device) illustrated in FIG. 6A, GL_{α} is a luminance value of the bottom of the trench, W_{β} is a trench width obtained from the SEM image 602 captured by the device β (serving as the correction target device) illustrated in FIG. 6B, and GL_{β} is a luminance value of the bottom of the trench. The trench width and the luminance value are calculated as average values of a plurality of trench patterns.

Depth index values I_{α} and I_{β} of the devices α and β are calculated by (Formula 3).

$${I}_{α} = {( {W}_{α} / {GL}_{α} )}^{N} \qquad ( Formula 3 )$$

$${I}_{β} = {( {W}_{β} / {GL}_{β} )}^{N}$$

In a state where the device difference is not corrected, the depth index values I_{α} and I_{β} are not the same value due to the device difference.

In Correction Method 3, the pattern dimension value and the luminance value inside the pattern are each corrected by a mathematical model. For example, when the pattern dimension value and the luminance value are corrected by a mathematical model of a linear formula, correction coefficients A_{CD} and B_{CD} for the pattern dimension value and correction coefficients A_{GL} and B_{GL} for the luminance value are calculated and these correction coefficients are registered in advance in the correction target device 1002.

The depth index value I_{β} of the correction target device 1002 is corrected to a depth index value I_{β}′ by using a trench width W_{β}′ and a luminance value GL_{β}′, which are corrected by a mathematical model using the correction coefficients, as expressed in (Formula 4).

$${W}_{β}^{′} = {A}_{CD} \cdot {W}_{β} + {B}_{CD} \qquad ( Formula 4 )$$

$${GL}_{β}^{′} = {A}_{GL} \cdot {GL}_{β} + {B}_{GL}$$

$${I}_{β}^{′} = {( {W}_{β}^{′} / {GL}_{β}^{′} )}^{N}$$

For the depth index value of an unclosed pattern such as a trench pattern, the device difference can be corrected by using (Formula 4).

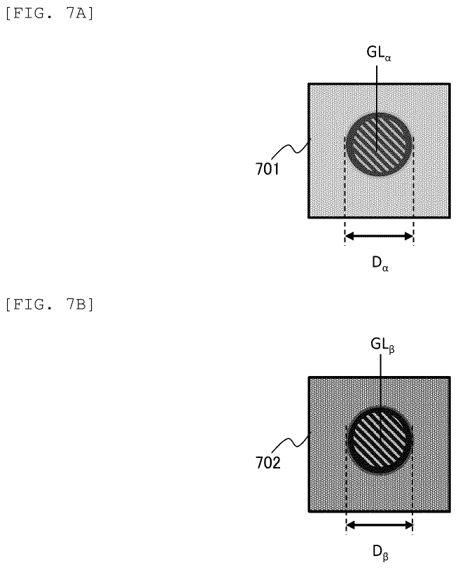

FIGS. 7A and 7B illustrate examples in which a pattern area and a luminance value are calculated from SEM images of the same hole pattern imaged by the depth inspection devices α and β. D_{α} is a hole diameter obtained from an SEM image 701 captured by the reference image (the device α) illustrated in FIG. 7A, GL_{α} is a luminance value of the bottom of the hole, D_{β} is a hole diameter obtained from an SEM image 702 captured by the correction target device (the device β) illustrated in FIG. 7B, and GL_{β} is a luminance value of the bottom of the hole. The hole diameter and the luminance value may be calculated as average values of a plurality of hole patterns as in the case of the trench pattern.

The depth index values I_{α} and I_{β} of the devices α and β are calculated by (Formula 5).

$${S}_{α} = π \cdot {( {D}_{α} / 2 )}^{2} \qquad ( Formula 5 )$$

$${S}_{β} = π \cdot {( {D}_{β} / 2 )}^{2}$$

$${I}_{α} = {S}_{α} / {( {GL}_{α} )}^{N}$$

$${I}_{β} = {S}_{β} / {( {GL}_{β} )}^{N}$$

In a state where the device difference is not corrected, the depth index values I_{α} and I_{β} are not the same value due to the device difference.

The depth index value I_{β} of the correction target device 1002 is corrected to the depth index value I_{β}′ by using a trench width DW_{β}′ and the luminance value GL_{β}′, which are corrected by a mathematical model using the correction coefficients, as expressed in (Formula 6).

$${D}_{β}^{′} = {A}_{CD} \cdot {D}_{β} + {B}_{CD} \qquad ( Formula 6 )$$

$${GL}_{β}^{′} = {A}_{GL} \cdot {GL}_{β} + {B}_{GL}$$

$${S}_{β}^{′} = π \cdot {( {D}_{β} / 2 )}^{2}$$

$${I}_{β}^{′} = {( {S}_{β}^{′} / {GL}_{β}^{′} )}^{N}$$

For the depth index value of a closed pattern such as a hole pattern, the device difference can be corrected by using (Formula 6). For a closed pattern other than the hole pattern, a device difference can be corrected similarly. A method of calculating an area S in accordance with a pattern shape may be applied.

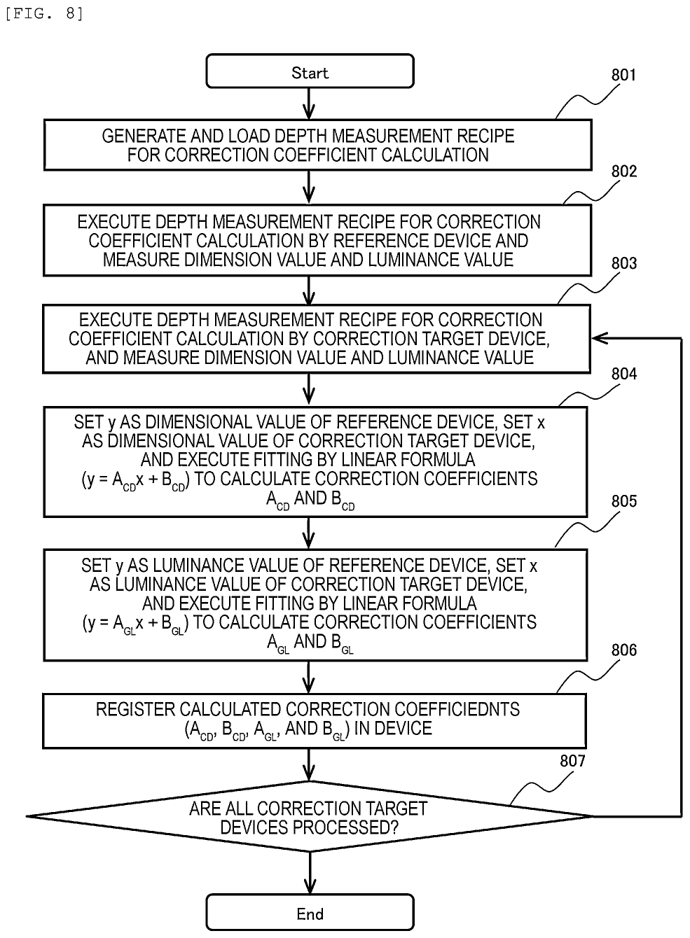

A procedure of calculating the correction coefficients A_{CD}, B_{CD}, A_{GL}, and B_{GL} when the device difference is corrected by Correction Method 3 is illustrated in a flowchart of FIG. 8.

In any one device (which may be the reference device or the correction target device) among the plurality of depth measurement devices, necessary information such as a layout of a wafer to be measured, coordinates of a measurement pattern, and a measurement condition is input from the input/output unit 104, and a depth measurement recipe (operation program) for correction coefficient calculation is generated and stored in the storage unit 105. The generated measurement recipe is loaded in the other depth measurement devices and is stored (step 801).

The reference device 1001 executes the depth measurement recipe for correction coefficient calculation and measures the pattern dimension value (step 802). Similarly, the correction target device 1002 executes the depth measurement recipe for correction coefficient calculation on the same sample and measures the pattern dimension value and the pattern luminance value (step 803).

On the assumption that y is a dimension value at each measurement point by the reference device 1001 and x is a dimension value at each measurement point by the correction target device, fitting is executed by a linear formula (y=A_{CD}x+B_{CD}) and the correction coefficients A_{CD} and B_{CD} are calculated (step 804). On the assumption that y is a luminance value at each measurement point by the reference device 1001 and x is a luminance value at each measurement point by the correction target device, fitting is executed by a linear formula (y=A_{GL}x+B_{GL}) and the correction coefficients A_{GL} and B_{GL} are calculated (step 805). The calculated correction coefficients A_{CD}, B_{CD}, A_{GL}, and B_{GL} are registered in the storage unit 105 of the correction target device 1002 (step 806). It is checked whether the correction coefficients are registered in all the correction target devices 1002. When there is a correction target device in which the correction coefficient is not registered, steps 803 to 806 are executed on that correction target device.

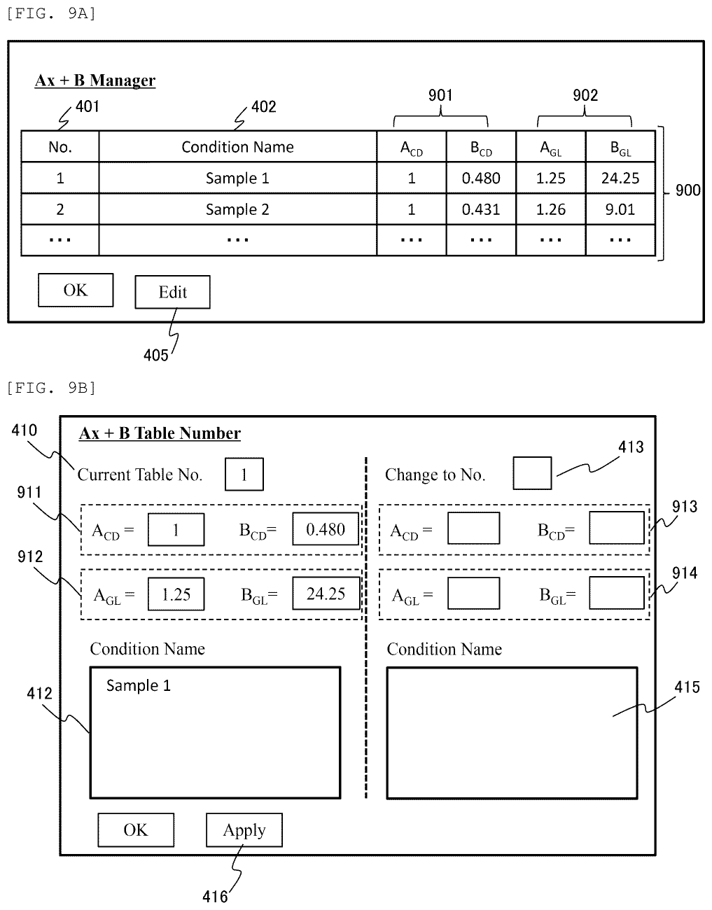

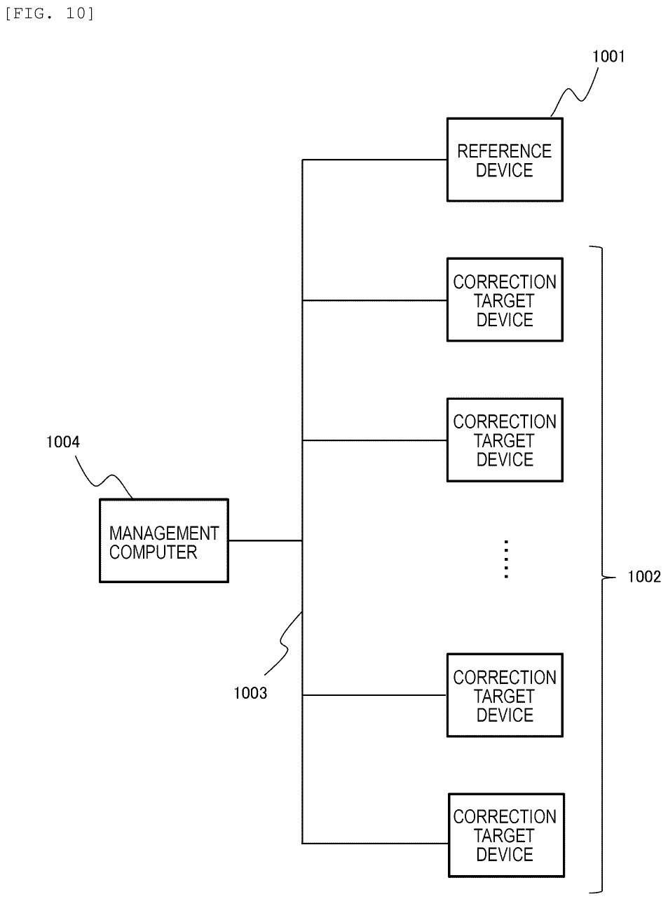

FIGS. 9A and 9B illustrate GUI screens for registering the correction coefficients A_{CD}, B_{CD}, A_{GL}, and B_{GL} in the correction target device 1002 in step 806. Since the GUI screens are the same as the GUI screens illustrated in FIGS. 4A and 4B, repeated description thereof will be omitted.

FIG. 9A illustrates a correction coefficient management screen. In a correction coefficient management table 900, the correction coefficients registered in the correction target device 1002 can be checked collectively. The correction coefficient management screen is similar to the correction coefficient management screen illustrated in FIG. 4A, but the correction coefficient values (A_{CD} and B_{CD}) 901 of the dimension values and the correction coefficient values (A_{GL} and B_{GL}) 902 of the luminance values are registered as the correction coefficient values. FIG. 9B illustrates a correction coefficient edit screen. The correction coefficient edit screen is similar to the correction coefficient edit screen illustrated in FIG. 4B, but a correction coefficient value display field 911 where correction coefficients of dimension values are displayed, a correction coefficient value display field 912 where correction coefficients of luminance values are displayed, and correction coefficient value input fields 913 and 914 where the correction coefficients of the dimension values and the correction coefficients of the luminance values obtained in the flowchart of FIG. 8 are input are provided.

In Correction Method 3, mathematical models for correcting the dimension values and the luminance values are generated, thereby making it possible to correct the device difference not only for the depth index values, but also for measurements using only the luminance values or for measured values calculated using the luminance values other than the depth index values.

### Example 2

In Example 2, an operation method of automatically calculating and managing correction coefficients necessary to correct a device difference by a mathematical model for the depth index values described in Example 1 and a depth measurement system will be described. In an aspect of a depth measurement system according to the present example, the plurality of depth measurement devices 1001 and 1002 are connected by the network 1003 so as to be able to access each other as in FIG. 2A. On the other hand, FIG. 10 illustrates another aspect of the depth measurement system according to the present example, and a management computer 1004 is further connected to the network 1003. The management computer 1004 has a function of managing the correction coefficients registered in each device.

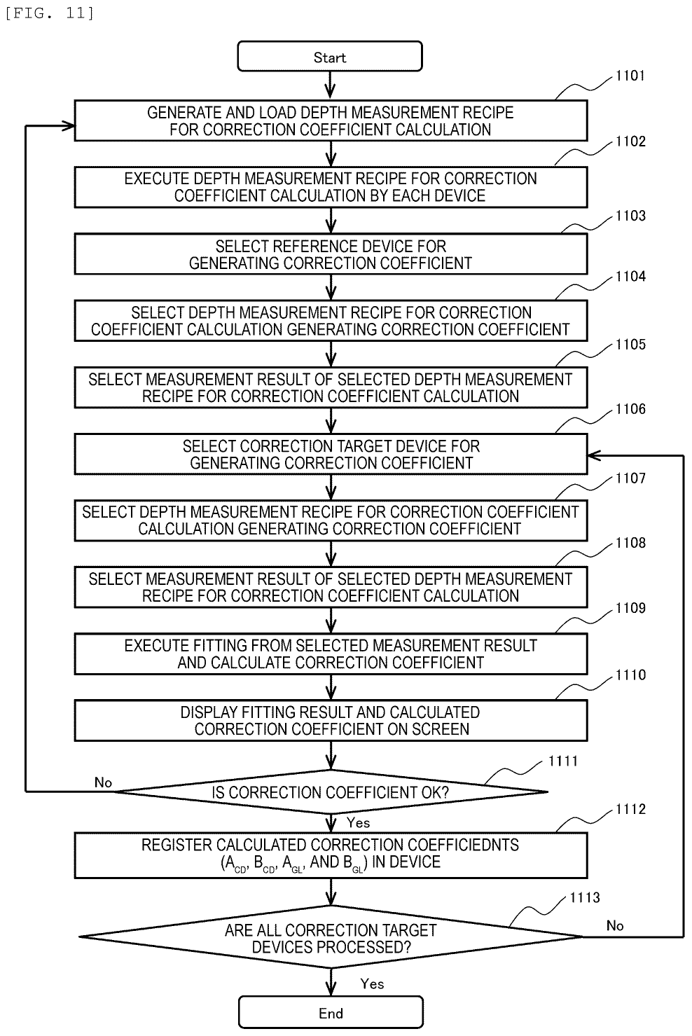

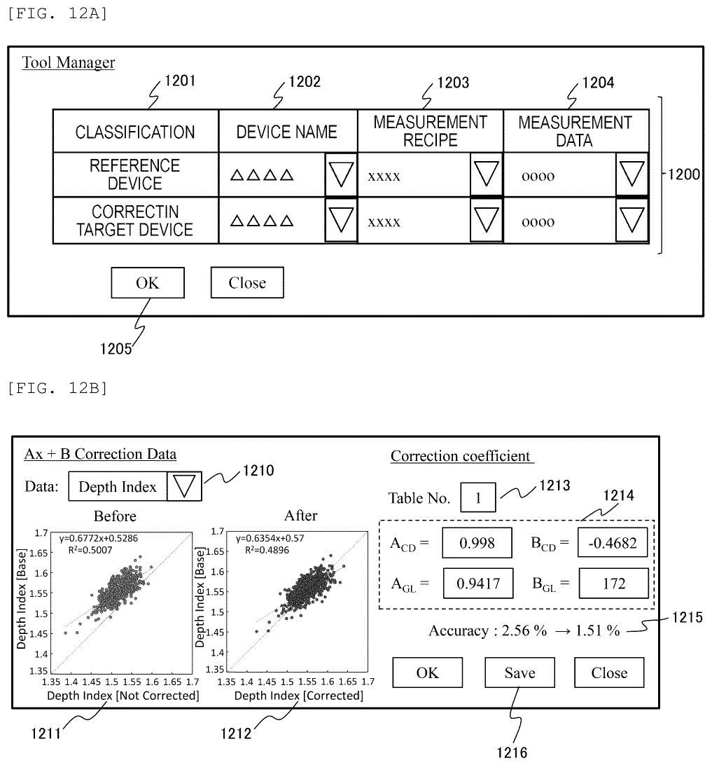

In the depth measurement system of FIG. 10, a procedure of calculating and operating the correction coefficients will be described using a flowchart of FIG. 11 and GUI screens of FIGS. 12A and 12B. Here, an example in which the correction coefficients based on Correction Method 3 described in Example 1 are calculated will be described. The same applies to a case where the correction coefficients based on another correction method are calculated.

Any one device among the plurality of depth measurement devices of the depth measurement system, necessary information such as a layout of a wafer to be measured, coordinates of a measurement pattern, and a measurement condition is input from the input/output unit 104, and a depth measurement recipe (operation program) for correction coefficient calculation is generated and stored in the storage unit 105. The generated measurement recipe is loaded in the other depth measurement devices and is stored (step 1101). Each device of the depth measurement system executes the depth measurement recipe for correction coefficient calculation and measures the pattern dimension values and the pattern luminance value (step 1102).

A selection screen illustrated in FIG. 12A is displayed on the management computer 1004. In a selection list 1200, classification of the reference device and the correction target devices is provided as classification 1201. In the selection list 1200, a device name field 1202, a measurement recipe field 1203, and a measurement data field 1204 are provided.

In a reference device record of the selection list 1200, the user selects a device name of the reference device in a pull-down manner from the device name field 1202 (step 1103). When the reference device is selected, the depth measurement recipe for correction coefficient calculation kept by the corresponding device can be selected. Accordingly, the user selects the depth measurement recipe for correction coefficient calculation kept by the reference device from the measurement recipe field 1203 in a pull-down manner (step 1104). When the depth measurement recipe for correction coefficient calculation is selected, measurement data acquired by the corresponding device executing the depth measurement recipe for correction coefficient calculation can be selected. Accordingly, the user selects the measurement data kept by the reference device from the measurement data field 1204 in a pull-down manner (step 1105).

Subsequently, in a correction target device record of the selection list 1200, the user selects a device name of the correction target device from the device name field 1202 in a pull-down manner (step 1106). When the correction target device is selected, the depth measurement recipe for correction coefficient calculation kept by the corresponding device can be selected. Accordingly, the user selects the depth measurement recipe for correction coefficient calculation kept by the correction target device from the measurement recipe field 1203 in a pull-down manner (step 1107). When the depth measurement recipe for correction coefficient calculation is selected, measurement data acquired by the corresponding device executing the depth measurement recipe for correction coefficient calculation can be selected. Accordingly, the user selects the measurement data kept by the correction target device from the measurement data field 1204 in a pull-down manner (step 1108).

When an execution button 1205 of the selection screen (see FIG. 12A) is pressed, the correction coefficients (A_{CD}, B_{CD}, A_{GL}, and B_{GL}) are calculated by executing fitting on measurement results of the selected reference device and correction target device (step 1109), and fitting results and calculated correction coefficients are displayed on a calculation result display screen illustrated in FIG. 12B (step 1110). The calculation result display screen is displayed on the management computer 1004.

The calculation result display screen illustrated in FIG. 12B will be described. A measurement result 1211 before correction application and a measurement result 1212 after correction application based on the calculated correction coefficients are displayed. The vertical axes represent a measurement result of the reference device in both the measurement results 1211 and 1212, the horizontal axis of the graph 1211 represents a measurement result of the correction target device before correction, and the horizontal axis of the graph 1212 represents a measurement result of the correction target device after correction. Accordingly, a correspondence relation between a value of the reference device and a value of the correction target device can be compared before and after correction. Data displayed as the measurement result can be selected in a data selection field 1210. Here, an example in which a depth index value is selected is described, but a dimension value or a luminance value can be selected in a pull-down manner. The correction coefficients calculated through the fitting are displayed on a correction coefficient display unit 1214 and inter-device difference indexes before and after correction are displayed on an inter-device difference index display unit 1215. The user checks whether the device difference is sufficiently reduced in the correction by the correction coefficients by comparing the displayed graphs 1211 and 1212 or checking a change in the inter-device difference index displayed in the inter-device difference index display unit 1215 (step 1111). For example, by comparing the graphs 1211 and 1212, it is possible to see that the depth index values after correction of the correction target device match the depth index values of the reference device compared to the depth index values before correction. Here, an inter-device difference index Acc is calculated by (Formula 7).

$$Acc = \vert average value of values x - average value of values y \vert / average value of values y \qquad ( Formula 7 )$$

Here, the values x are depth index values or measured values of the correction target device, and the values y are depth index values or measured values of the reference device. The values are assumed to be the depth index values or the measured values selected in the data selection field 1210. The smaller a difference between the average value of the values x and the average value of the values y is, the smaller the value of the index Acc is.

When the correction coefficients are not appropriate (No in step 1111), the measurement condition of the depth measurement recipe for correction coefficient calculation is reexamined and the process is executed again from step 1101. When the correction coefficients are appropriate (Yes in step 1111), the calculated correction coefficients are registered in the correction target device by setting a management number in the management number input field 1213 on the calculation result display screen (see FIG. 12B) and pressing a save button 1216 (step 1112). At this time, the measurement target and the measurement condition may be automatically registered on the condition that the correction coefficients can be applied. Accordingly, the measurement target and the measurement condition are displayed in the correction coefficient management table 900 (see FIG. 9A). Accordingly, this process is executed on all the correction target device (step 1113). In this way, the management computer 1004 can calculate and manage the correction coefficients of all the correction target devices in the depth measurement system.

In the case of the depth measurement system illustrated in FIG. 2A, a flowchart of FIG. 11 can be executed by executing the processes from steps 1104 to 1112 for each correction target device. In this case, each correction target device calculates and manages the correction coefficients applied to the corresponding device. That is, the correction target device in step 1106 is the corresponding device, and the display screens of FIGS. 12A and 12B are displayed on the computer of the corresponding device.

In the present example, the user can select appropriate measurement data in accordance with a program of the depth measurement system, and thus it is possible to calculate and register the correction coefficient simply and reduce a device difference of the measured value.

### REFERENCE SIGNS LIST

100: computer
101: imaging unit
102: whole control unit
103: signal processing unit
104: input/output unit
105: storage unit
106: electron gun
107: electron beam
108, 109: focusing lens
110: deflector
111: objective lens
112: sample
113: stage
114: emission electron
115: deflector
116: detection diaphragm
119, 121: detector
120: cubic electron
122: energy filter
123: deflector
130: shutter
131: blanking deflector
132: blanking electrode
400: correction coefficient management table
401: management number
402: condition name
403, 404, 901, 902: correction coefficient value
405: edit button
410: management number display field
411, 911, 912: correction coefficient value display field
412: condition name display field
413: management number input field
414, 913, 914: correction coefficient value input field
415: condition name input field
416: application button
601, 602, 701, 702: SEM image
1001: reference device
1002: correction target device
1003: network
1004: management computer
1200: selection list
1201: classification
1202: device name field
1203: measurement recipe field
1204: measurement data field
1205: execution button
1210: data selection field
1211, 1212: measurement result
1213: management number input field
1214: correction coefficient display unit
1215: inter-device difference index display unit
1216: save button

1. A depth measurement system comprising a plurality of depth measurement devices, each of the plurality of depth measurement devices calculating a depth index value indicating a relative depth of a pattern on a sample,
wherein each of the depth measurement devices includes
an electron optical system that irradiates the sample with an electron beam,
a detection system that detects an emission electron emitted from the sample irradiated with the electron beam, and
a computer that controls the electron optical system and the detection system by executing a depth measurement recipe that is an operation program measuring a depth of a predetermined pattern in a measurement target and calculates the depth index value of the predetermined pattern based on a measured value extracted from an electron image formed from an output from the detection system,
wherein the plurality of depth measurement devices are classified into one reference device and the other correction target devices, and
wherein the computer of the correction target device stores a correction coefficient associated with the depth measurement recipe and outputs the depth index value of the predetermined pattern corrected using a mathematical model to which the correction coefficient is applied.

2. The depth measurement system according to claim 1,
wherein the plurality of depth measurement devices control the electron optical system and the detection system by executing a depth measurement recipe for correction coefficient calculation with the same measurement condition as the depth measurement recipe, extract the measured value from the output of the detection system, or calculate the depth index value of the predetermined pattern of the measurement target based on the extracted measured value, and
wherein the correction coefficient is a correction coefficient obtained by fitting the measured value extracted by executing the depth measurement recipe for correction coefficient calculation by the correction target device to the measured value extracted by executing the depth measurement recipe for correction coefficient calculation by the reference device in accordance with the mathematical model, or is a correction coefficient obtained by fitting the depth index value calculated by executing the depth measurement recipe for correction coefficient calculation by the correction target device to the depth index value calculated by executing the depth measurement recipe for correction coefficient calculation by the reference device.

3. The depth measurement system according to claim 1,
wherein the mathematical model is expressed as I_{c}=A·Iₒ+B, and
wherein I_{c} is the depth index value after correction, Iₒ is the depth index value before correction, and A and B are the correction coefficients.

4. The depth measurement system according to claim 1,
wherein the mathematical model is expressed as I_{c}=Iₒ+B, and
wherein I_{c} is the depth index value after correction, Iₒ is the depth index value before correction, and B is the correction coefficient.

5. The depth measurement system according to claim 1,
wherein the depth index value is expressed as a function of a dimension value of a pattern and a luminance value inside the pattern,
wherein the mathematical model is expressed as W_{c}=A_{CD}·Wₒ+B_{CD} and GL_{c}=A_{GL}·GLₒ+B_{GL}, and
wherein W_{c} is a dimension value of the pattern after correction, Wₒ is a dimension value of the pattern before correction, GL_{c} is a luminance value inside the pattern after correction, GLₒ is a luminance value inside the pattern before correction, and A_{CD}, B_{CD}, A_{GL}, GLₒ, and B_{GL} are the correction coefficients.

6. The depth measurement system according to claim 1,
wherein the computer of the correction target device stores a condition to which the correction coefficient is applied, and
wherein the condition includes a measurement condition for acquiring the measurement target and the electron image.

7. The depth measurement system according to claim 2,
wherein the plurality of depth measurement devices are connected to a network, and
wherein the correction target device acquires the measured value extracted or the depth index value calculated by executing the depth measurement recipe for correction coefficient calculation by the reference device via the network and calculates the correction coefficient.

8. The depth measurement system according to claim 7, wherein the computer of the correction target device comparably displays a correspondence relation between the measured value by the reference device and the measured value before correction by the correction target device and a correspondence relation between the measured value by the reference device and the measured value after correction by the correction target device, or comparably displays a correspondence relation between the depth index value by the reference device and the depth index value before correction by the correction target device and a correspondence relation between the depth index value by the reference device and the depth index value after correction by the correction target device.

9. The depth measurement system according to claim 8, wherein the computer of the correction target device calculates an inter-device difference index indicating a difference between the measured value or the depth index value by the reference device and the measured value or the depth index value by the correction target device and displays a change in the inter-device difference index before and after correction.

10. The depth measurement system according to claim 2, further comprising a management computer,
wherein the plurality of depth measurement devices and the management computer are connected by a network, and
wherein the management computer acquires the measured value extracted or the depth index value calculated by executing the depth measurement recipe for correction coefficient calculation by the reference device and the measured value extracted or the depth index value calculated by executing the depth measurement recipe for correction coefficient calculation by the correction target device via the network and calculates the correction coefficient of the correction target device.

11. The depth measurement system according to claim 10, wherein the management computer comparably displays a correspondence relation between the measured value by the reference device and the measured value before correction by the correction target device and a correspondence relation between the measured value by the reference device and the measured value after correction by the correction target device, or comparably displays a correspondence relation between the depth index value by the reference device and the depth index value before correction by the correction target device and a correspondence relation between the depth index value by the reference device and the depth index value after correction by the correction target device.

12. The depth measurement system according to claim 11, wherein the management computer calculates an inter-device difference index indicating a difference between the measured value or the depth index value by the reference device and the measured value or the depth index value by the correction target device and displays a change in the inter-device difference index before and after correction.

13. A depth index calculation method in a depth measurement system including a plurality of depth measurement devices and calculating a depth index value indicating a relative depth of a measurement target pattern,
wherein each of the depth measurement devices includes
an electron optical system that irradiates the sample with an electron beam,
a detection system that detects an emission electron emitted from the sample irradiated with the electron beam, and
a computer that controls the electron optical system and the detection system by executing a depth measurement recipe that is an operation program measuring a depth of a predetermined pattern in a measurement target and calculates the depth index value of the predetermined pattern based on a measured value extracted from an electron image formed from an output from the detection system,
wherein the plurality of depth measurement devices are classified into one reference device and the other correction target devices,
wherein the computer of the correction target device stores a correction coefficient associated with the depth measurement recipe,
wherein the reference device outputs the depth index value calculated by executing the depth measurement recipe, and
wherein the correction target device corrects and outputs the depth index value calculated by executing the depth measurement recipe using a mathematical model to which the correction coefficient is applied.

14. The depth index calculation method according to claim 13,
wherein the plurality of depth measurement devices control the electron optical system and the detection system by executing a depth measurement recipe for correction coefficient calculation with the same measurement condition as the depth measurement recipe, extract the measured value from an electron image formed from the output of the detection system, or calculate the depth index value of the predetermined pattern of the measurement target based on the extracted measured value, and
wherein the correction coefficient is a correction coefficient obtained by fitting the measured value extracted by executing the depth measurement recipe for correction coefficient calculation by the correction target device to the measured value extracted by executing the depth measurement recipe for correction coefficient calculation by the reference device in accordance with the mathematical model, or is a correction coefficient obtained by fitting the depth index value calculated by executing the depth measurement recipe for correction coefficient calculation by the correction target device to the depth index value calculated by executing the depth measurement recipe for correction coefficient calculation by the reference device.

15. The depth index calculation method according to claim 14,
wherein the plurality of depth measurement devices are connected to a network, and
wherein the correction target device acquires the measured value extracted or the depth index value calculated by executing the depth measurement recipe for correction coefficient calculation by the reference device via the network and calculates the correction coefficient.

16. The depth index calculation method according to claim 14,
wherein the depth measurement system includes a management device, and the plurality of depth measurement devices and the management computer are connected to a network, and
wherein the management computer acquires the measured value extracted or the depth index value calculated by executing the depth measurement recipe for correction coefficient calculation by the reference device and the measured value extracted or the depth index value calculated by executing the depth measurement recipe for correction coefficient calculation by the correction target device via the network and calculates the correction coefficient of the correction target device.

17. A depth measurement device calculating a depth index value indicating a relative depth of a pattern on a sample, the device comprising:
an electron optical system that irradiates the sample with an electron beam;
a detection system that detects an emission electron emitted from the sample irradiated with the electron beam; and
a computer that controls the electron optical system and the detection system by executing a depth measurement recipe that is an operation program measuring a depth of a predetermined pattern in a measurement target and calculates the depth index value of the predetermined pattern based on a measured value extracted from an electron image formed from an output from the detection system,
wherein, in a depth measurement system including a plurality of the depth measurement devices, the plurality of the depth measurement devices are classified into one reference device and the other correction target devices, and
wherein, when the depth measurement device is classified as the correction target device, the computer stores a correction coefficient associated with the depth measurement recipe and outputs the depth index value of the predetermined pattern corrected using a mathematical model to which the correction coefficient is applied.

18. The depth measurement device according to claim 17,
wherein the computer controls the electron optical system and the detection system by executing a depth measurement recipe for correction coefficient calculation with the same measurement condition as the depth measurement recipe, extracts the measured value from an electron image formed from the output of the detection system, or calculates the depth index value of the predetermined pattern of the measurement target based on the extracted measured value, and
wherein the correction coefficient is a correction coefficient obtained by fitting the measured value extracted by executing the depth measurement recipe for correction coefficient calculation classified into the correction target device to the measured value extracted by executing the depth measurement recipe for correction coefficient calculation classified into the reference device in accordance with the mathematical model, or is a correction coefficient obtained by fitting the depth index value calculated by executing the depth measurement recipe for correction coefficient calculation classified into the correction target device to the depth index value calculated by executing the depth measurement recipe for correction coefficient calculation classified into the reference device.
